(19) United States
(12) Patent Application Publication
(10) Pub. No.: US 2002/0160589 A1
(43) Pub. Date: Oct. 31, 2002

(54) Semiconductor element and method of manufacturing the same

(76) Inventor: Toshihiko Omi, Chiba-shi (JP)

Correspondence Address: ADAMS & WILKS, 31st Floor, 50 Broadway, New York, NY, 10004, US

(21) Appl. No.: 09/864,940

(22) Filed: May 24, 2001

(30) Foreign Application Priority Data
Jun. 2, 2000 (JP) 2000-166213
Sep. 8, 2000 (JP) 2000-272727
Sep. 8, 2000 (JP) 2000-272728
Apr. 11, 2001 (JP) 2001-113034

(51) Int. Cl. H01L 21/04; H01L 21/425

(52) U.S. Cl. 438/527; 438/510; 438/514

(57) ABSTRACT

There is a method of manufacturing a semiconductor element with a variety of types and at low cost.

In the semiconductor element formed on a semiconductor substrate manufactured by manufacture of at least two semiconductor substrates in a batch manner, a semiconductor element formed on an arbitrary semiconductor substrate manufactured in a batch manner and a semiconductor element formed on at least one of the rest of the semiconductor substrates manufactured in a batch manner are different from each other.

### DETAILED DESCRIPTION OF THE INVENTION

1. Technical FIeld to which the Invention belongs

The present invention relates to a semiconductor element that is applied to a wide range of fields of household apparatus, AV apparatus, information equipment, communication equipment, car-electric mounting equipment and the like.

2. Prior Art

Semiconductor elements with the same specifications and standard can be mass-produced by generally manufacturing several tens of semiconductor substrates or more in a batch manner. Thus, standardized articles of the semiconductor elements at a low price and with high quality have been provided.

3. Problem to be Solved by the Invention

However, with diversification of value in recent years, a small amount and a variety of semiconductor elements has been required. As described above, the standardized articles of the semiconductor elements at a low price and with high quality have been provided. This originates in the manufacture of several tens of semiconductor substrates or more in a batch manner. On the other hand, there are many cases where the manufacture of one to several semiconductor substrates in a batch manner is sufficient for providing a small amount and a variety of semiconductor elements. In this case, the characteristic of a semiconductor element manufacture can not be utilized, and it is difficult to provide semiconductor elements at a low price and with high quality.

The present invention has been made in view of the above, and an object of the present invention is therefore to provide a semiconductor element at a low price and with high quality by manufacture of semiconductor elements with different standards and specifications in a batch manner.

### MEANS FOR SOLVING THE PROBLEM

In the present invention, a semiconductor element and a method of manufacturing the semiconductor element are characterized by, the semiconductor element being formed on a semiconductor substrate manufactured by manufacture of at least two semiconductor substrates in a batch manner, and being the semiconductor element in which a semiconductor element formed on an arbitrary semiconductor substrate manufactured in a batch manner and a semiconductor element formed on at least one of the rest of the semiconductor substrates manufactured in a batch manner are different from each other.

In order to manufacture a semiconductor element with different standards and specifications, in a semiconductor element and a method of manufacturing the semiconductor element, the semiconductor element being formed on a semiconductor substrate manufactured by manufacture of at least two semiconductor substrates in a batch manner, and being the semiconductor element in which a semiconductor element formed on an arbitrary semiconductor substrate manufactured in a batch manner and a semiconductor element formed on at least one of the rest of the semiconductor substrates manufactured in a batch manner are different from each other, it is characterized that all the heating steps are performed with the manufacture in a batch manner or all the heating steps except for only an arbitrary heating step with an arbitrary semiconductor substrate are performed with the manufacture in a batch manner in a manufacturing process of the semiconductor element, or it is characterized in that the semiconductor substrate on which the semiconductor element different from the arbitrary semiconductor element is formed comprises at least one of a photoengraving step of photoengraving a different original picture in an arbitrary photoengraving step and an impurity ion injecting step for injecting different impurity ions or different amounts of ions in an arbitrary impurity ion injecting step.

As a means for realizing a manufacturing method of the present invention, there is provided a method of manufacturing a semiconductor element by a photoengraving device which is characterized by comprising a container for containing at least two masks, a conveyance mechanism for conveying a desired mask from the container to an exposure portion for photoengraving and for conveying the mask having been subjected to an exposure step from the exposure portion to the container, a storage equipment for previously storing at least one of an arbitrary manufacturing lot, a wafer thereof, and a mask that an arbitrary wafer of the lot desires, and a control equipment for instructing on conveyance of a mask corresponding to the arbitrary wafer of the arbitrary lot, which is stored, and on exposure. In accordance with the manufacturing method by this photoengraving device, a necessary mask is automatically selected to conduct the exposure process by previously storing in the device the necessary masks for the respective wafers of the lot to be processed. Thus, photoengraving of different masks for every wafer in the same lot can be easily realized. Therefore, at least two types of ICs can be easily manufactured in a batch manner.

The photoengraving device is provided with an inspection equipment for dust attached on a mask, a mask cleaning equipment, and a remaining heat chamber for maintaining at least one mask at an arbitrary temperature. Further, a function is added, which is for previously and automatically conducting preparation required for setting the desirable stored maskin the exposure portion. Thus, the time necessary for exchanging the mask to be exposed can be reduced, and the productivity can be maintained in case of the exposure of a plurality of masks in the same lot.

In a case where at least two of the photoengraving devices are used, a common mask container is not necessary by previously determining the photoengraving step used by an arbitrary photoengraving device. Further, each of the photoengraving devices is provided with a small-sized mask container, and thus, a mask conveyance system of the photoengraving device can be simple and reduced in size.

Moreover, as a means for realizing a manufacturing method of the present invention, there is provided a semiconductor element and a method of manufacturing the semiconductor element manufactured by a photoengraving device in which an arbitrary mask original picture is transferred on a photosensitive film applied to a semiconductor substrate, characterized in that the mask original picture comprises an original picture displayed on an electronic display by inputting desired data. In accordance with the manufacturing method by this photoengraving device, photoengraving of different mask original pictures for every wafer in the same lot can be easily realized by previously inputting in the photoengraving device the mask original picture data necessary for the respective wafers of the lot to be processed. Thus, at least two types of ICs can be easily manufactured in a batch manner. The electronic display for displaying the mask original picture of the photoengraving device can be constituted of a matrix display liquid crystal panel or the like.

Furthermore, with a method of manufacturing a semiconductor element by a photoengraving device for transferring an arbitrary original picture, on a photosensitive film applied onto a semiconductor substrate, of a semiconductor element being formed on a semiconductor substrate manufactured by manufacture of at least two semiconductor substrates in a batch manner, and being characterized in that a semiconductor element formed on an arbitrary semiconductor substrate manufactured in a batch manner and a semiconductor element formed on at least one of the rest of the substrates manufactured in a batch manner are different from each other, and of a method of manufacturing the semiconductor element, characterized in that: the photoengraving device is constituted of a light source for exposing the photosensitive film, a lens for guiding light to the photosensitive film from the light source, a mirror array in which a plurality of minute mirrors are arranged in an array, a driving device for moving the minute mirrors of the mirror array in an arbitrary angle, and a control equipment thereof; the light source, the lens, the mirror array are arranged such that the light from the light source is reflected at the mirror array to reach the photosensitive film; the minute mirrors are driven by the driving device to be moved to at least two positions corresponding with an angle such that the reflected light reaches the photosensitive film of the minute mirror and an angle so that the reflected light does not reach the photosensitive film; and the control equipment controls such that the entire mirror array reflects an arbitrary image onto the photosensitive film, photoengraving of different mask original pictures for every wafer in the same lot can be easily realized by previously inputting in the photoengraving device the mask original picture data necessary for the respective wafers of the lot to be processed. Thus, at least two types of ICs can be easily manufactured in a batch manner.

### BRIEF DESCRIPTION OF THE DRAWINGS

FIG. 1 is across-sectional view according to a first embodiment of the present invention.

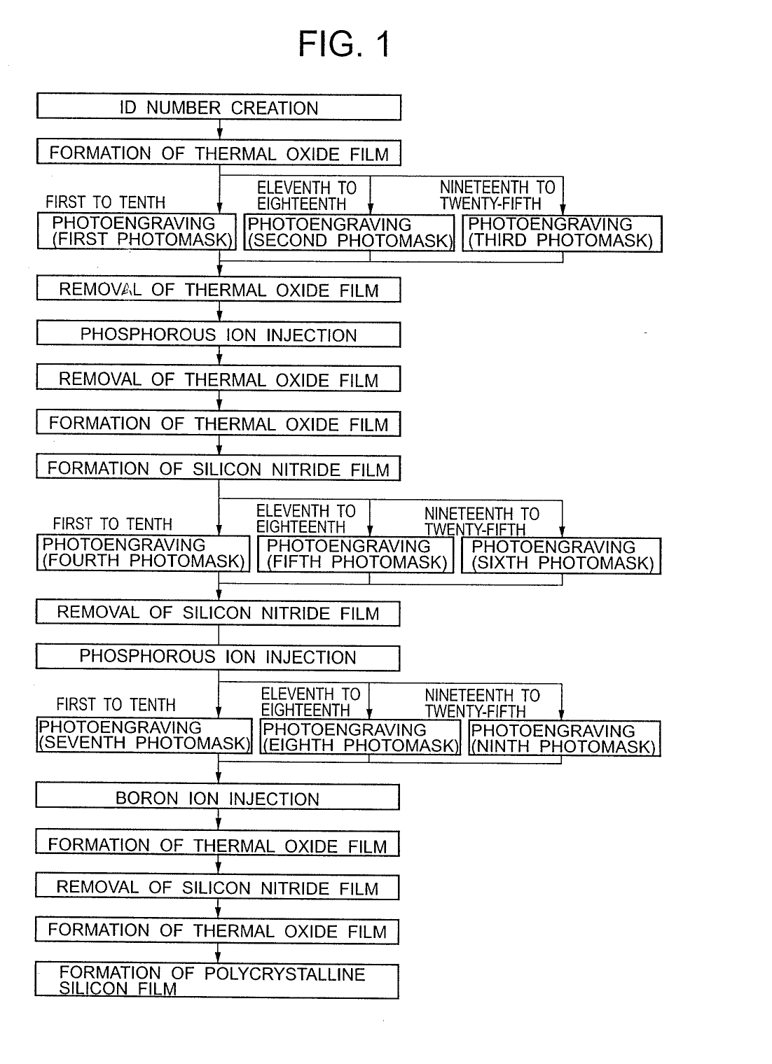

FIG. 2 is a cross-sectional view according to a second embodiment of the present invention (continuation).

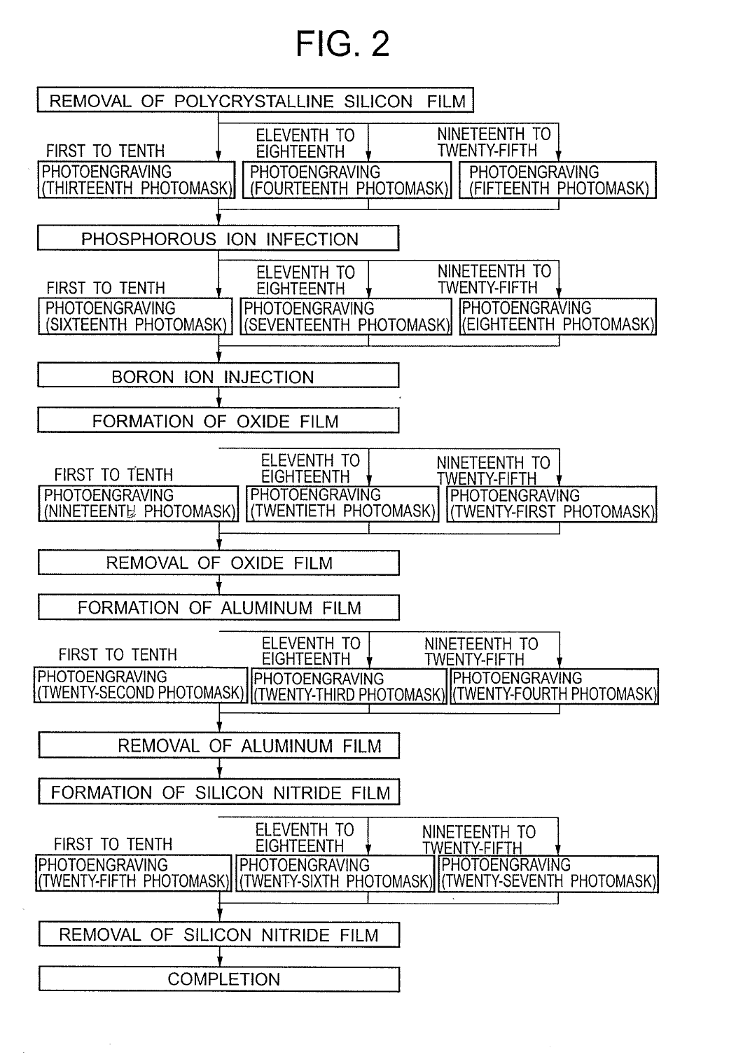

FIG. 3 is a functional block diagram of a photoengraving device of the present invention.

FIG. 4 is a functional block diagram of a second photoengraving device of the present invention.

FIG. 5 is a schematic diagram 1 of an exposure portion of the photoengraving device of the present invention.

FIG. 6 is a schematic diagram 2 of the exposure portion of the photoengraving device of the present invention.

### DETAILED DESCRIPTION OF THE INVENTION

Embodiment Mode of the Invention

In this embodiment, an example of manufacture in a batch manner in which, among twenty-five p-type silicon substrates, first semiconductor elements, second semiconductor elements, and third semiconductor elements are formed of the first to tenth silicon substrates, the eleventh to eighteenth silicon substrates, and the nineteenth to twenty-fifth silicon substrates, respectively, is described.

At first, ID numbers are engraved on the first to twenty-fifth silicon substrates with laser. Next, the first to twenty-fifth silicon substrates are simultaneously heated to form thermal oxide films. The first to tenth silicon substrates, the eleventh to eighteenth silicon substrates, and the nineteenth to twenty-fifth silicon substrates are photoengraved using a first photomask, a second photomask, and a third photomask, respectively. The thermal oxide films are removed from the first to twenty-fifth silicon substrates in accordance with the photoengraved shapes, and n-type regions (N−) are formed by injecting phosphorous ions. Then, the thermal oxide films are completely and simultaneously removed from the first to twenty-fifth silicon substrates, thermal oxide films are formed again, and silicon nitride films are formed by a CVD method. The first to tenth silicon substrates, the eleventh to eighteenth silicon substrates, and the nineteenth to twenty-fifth silicon substrates are photoengraved using a fourth photomask, a fifth photomask, and a sixth photomask, respectively. The silicon nitride films are removed from the first to twenty-fifth silicon substrates in accordance with the photoengraved shapes, and n-type regions (N±) are formed by injecting phosphorous ions. The first to tenth silicon substrates, the eleventh to eighteenth silicon substrates, and the nineteenth to twenty-fifth silicon substrates are photoengraved using a seventh photomask, an eighth photomask, and a ninth photomask, respectively. Boron ions are injected into the first to twenty-fifth silicon substrates to form p-type regions (p±). Next, the first to twenty-fifth silicon substrates are simultaneously heated to form thermal oxide films, and the silicon nitride films are completely removed. Again, the first to twenty-fifth silicon substrates are simultaneously heated to form thermal oxide films, and polycrystalline silicon films are formed by a CVD method. The first to tenth silicon substrates, the eleventh to eighteenth silicon substrates, and the nineteenth to twenty-fifth silicon substrates are photoengraved using a tenth photomask, an eleventh photomask, and a twelfth photomask, respectively. The polycrystalline silicon films are removed from the first to twenty-fifth silicon substrates in accordance with the photo engraved shapes. The first to tenth silicon substrates, the eleventh to eighteenth silicon substrates, and the nineteenth to twenty-fifth silicon substrates are photoengraved using a thirteenth photomask, a fourteenth photomask, and a fifteenth photomask, respectively. Phosphorous ions are injected into the first to twenty-fifth silicon substrates with the photoengraved shapes to form n-type regions (N+). The first to tenth silicon substrates, the eleventh to eighteenth silicon substrates, and the nineteenth to twenty-fifth silicon substrates are photoengraved using a sixteenth photomask, a seventeenth photomask, and an eighteenth photomask, respectively. Boron ions are injected into the first to twenty-fifth silicon substrates with the photoengraved shapes to form p-type regions (P+). Subsequently, oxide films are simultaneously formed on the first to twenty-fifth silicon substrates by the CVD method, and thereafter, heat processing is conducted thereon. The first to tenth silicon substrates, the eleventh to eighteenth silicon substrates, and the nineteenth to twenty-fifth silicon substrates are photoengraved using a nineteenth photomask, a twentieth photomask, and a twenty-first photo mask, respectively. The silicon oxide films are removed from the first to twenty-fifth silicon substrates in accordance with the photoengraved shapes. Next, aluminum films are simultaneously formed on the first to twenty-fifth silicon substrates by sputtering. The first to tenth silicon substrates, the eleventh to eighteenth silicon substrates, and the nineteenth to twenty-fifth silicon substrates are photoengraved using a twenty-second photomask, a twenty-third photomask, and a twenty-fourth photomask, respectively. The aluminum films are removed from the first to twenty-fifth silicon substrates in accordance with the photoengraved shapes. Then, silicon nitride films are simultaneously formed on the first to twenty-fifth silicon substrates by the CVD method, and thereafter, heat processing is conducted thereon. The first to tenth silicon substrates, the eleventh to eighteenth silicon substrates, and the nineteenth to twenty-fifth silicon substrates are photoengraved using a twenty-fifth photomask, a twenty-sixth photomask, and a twenty-seventh photomask, respectively. Finally, the silicon nitride films are removed from the first to twenty-fifth silicon substrates in accordance with the photoengraved shapes. Thus, the manufacture in a batch manner is completed, in which the first semiconductor elements, the second semiconductor elements, and the third semiconductor elements are formed of the first to tenth silicon substrates, the eleventh to eighteenth silicon substrates, and the nineteenth to twenty-fifth silicon substrates, respectively.

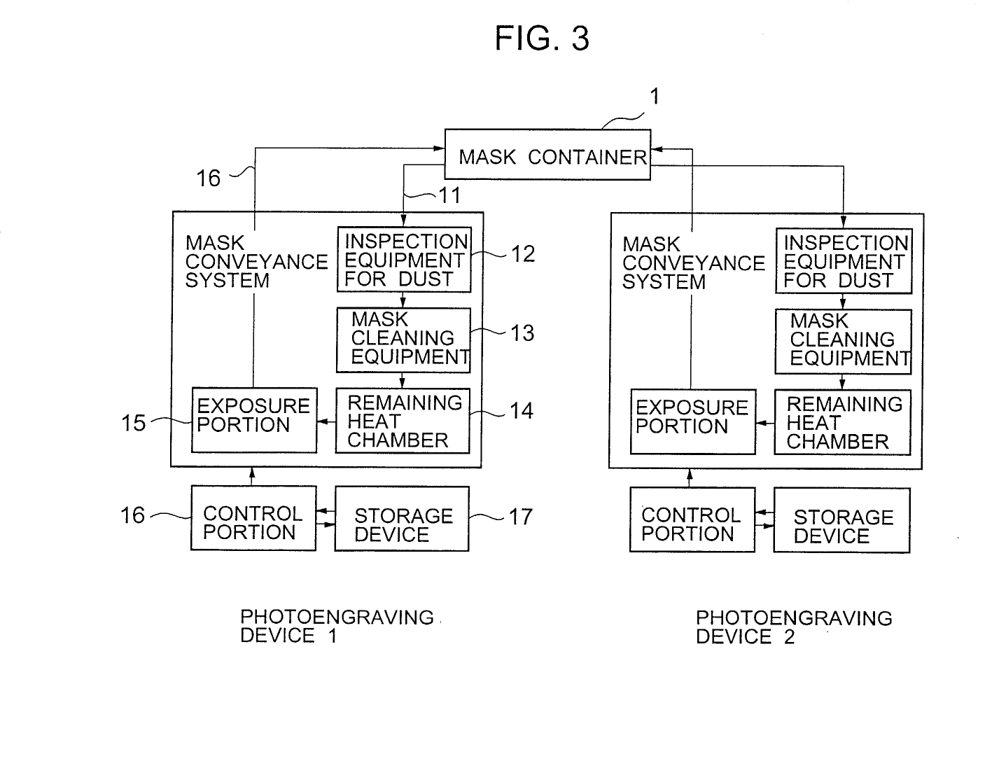

FIG. 3 is a functional block diagram of a photoengraving device used in the manufacturing method of the embodiment. Masks are generally kept in a container 1. The required masks in an arbitrary photoengraving process are conveyed to an inspection equipment 12 for dust on a mask and a mask cleaning equipment 13 in a conveyance system 11 from the container 1. After being examined and cleaned, the masks are transferred to a remaining heat chamber 14. At this time, the plural masks used in the photoengraving process are conveyed to the remaining heat chamber 14. Next, in the photoengraving process, the masks corresponding to arbitrary wafers are transferred from the remaining heat chamber 14 to an exposure portion 15, and photoengraving is conducted on the wafers. After the completion of photoengraving on all the wafers in the photoengraving process, the masks are conveyed to the container 1 for masks through a conveyance system 16. All the operation described above is controlled by a control portion 18. Further, the masks required in the photoengraving process are stored in advance in a storage device 17.

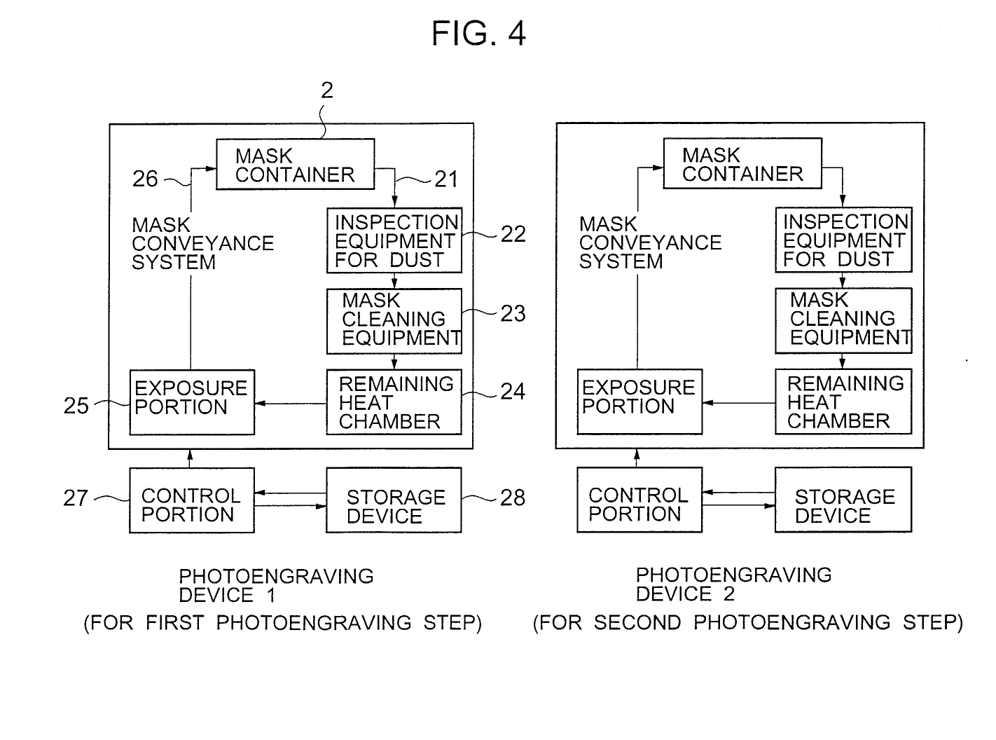

In this embodiment, a plurality of photoengraving devices use a single mask container. However, as shown in FIG. 4, it may be that a photoengraving process used by an arbitrary photoengraving device is determined in advance, and thus, each of the photoengraving devices may have a small-sized mask container. In this case as well, the operation of the device is the same as in the embodiment of FIG. 3.

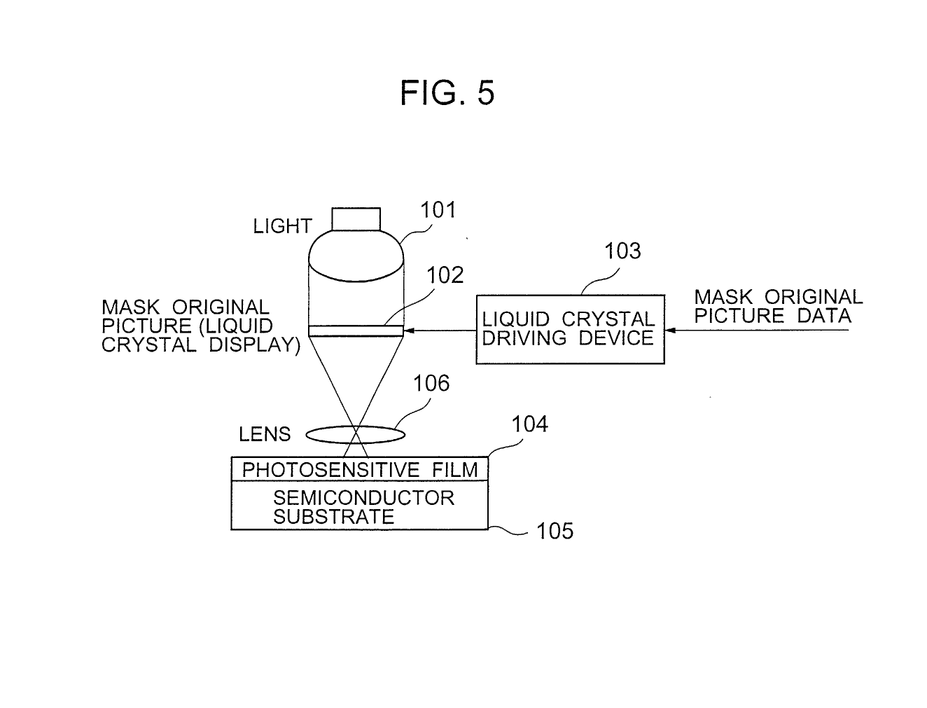

FIG. 5 is a schematic diagram of an exposure portion of the photoengraving device used in the manufacturing method of the embodiment. In this embodiment, a transmission type liquid crystal panel enclosed in a quartz substrate is used as an electronic display.

Ultraviolet light from a light source 101 exposes the same picture as a mask original picture 102 on a photosensitive film 104 applied onto a semiconductor substrate 105 by an imaging lens 106 through the mask original picture 102. A transmission type liquid crystal enclosed in a quartz substrate is used for the mask original picture 102, and an arbitrary image formed in a driving device 103 is formed.

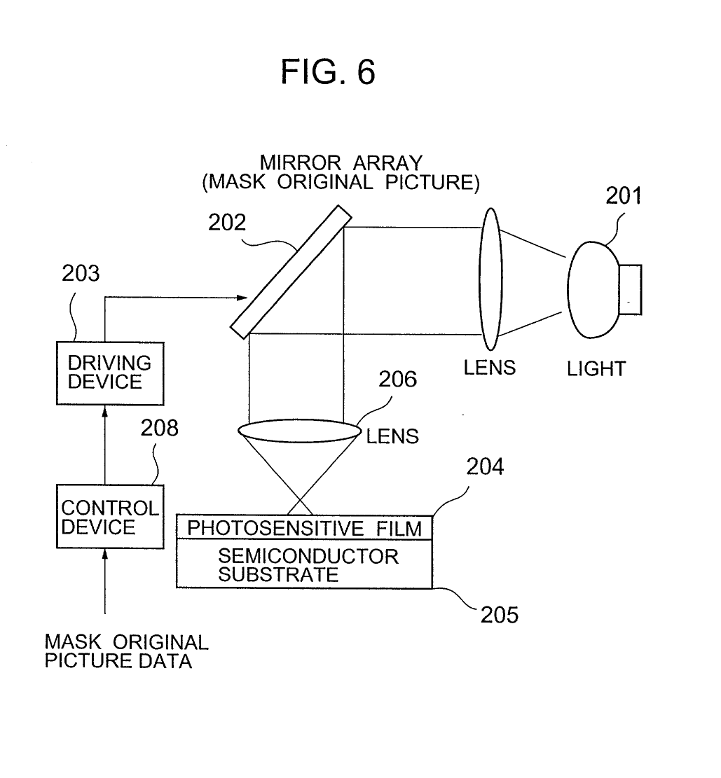

FIG. 6 is a schematic diagram of an exposure portion of a photoengraving device using a mirror array, which is used in the manufacturing method of the embodiment.

Ultraviolet light from a light source 201 passes through a collimate lens 207 and is reflected at a mask original picture 202. The reflected ultraviolet light exposes the same picture as the mask original picture on a photosensitive film 204 applied onto a semiconductor substrate 205 through an imaging lens 206. The mask original picture 202 is an accumulation of about five million pieces of minute mirrors, and the mirror array is generally maintained at an angle such that light does not reach the photosensitive film 204. The mirror array is appropriately moved to an angle such that light reaches the photosensitive film 204 by a driving device 203, and thus, an arbitrary image is formed on the photosensitive film 204.

### EFFECTS OF THE INVENTION

According to the present invention, there can be provided a small amount and a variety of semiconductor elements at a low price and with high quality by the manufacture of the semiconductor elements in a batch manner with different standards and specifications.

1. A semiconductor element formed on a semiconductor substrate manufactured by manufacture of at least two semiconductor substrates in a batch manner, wherein a semiconductor element formed on an arbitrary semiconductor substrate manufactured in a batch manner and a semiconductor element formed on at least one of the rest of the semiconductor substrates manufactured in a batch manner are different from each other.

2. A semiconductor element as claimed in claim 1, the semiconductor element being formed on a semiconductor substrate manufactured by the manufacture of at least two semiconductor substrates in a batch manner, and being the semiconductor element in which a semiconductor element formed on an arbitrary semiconductor substrate manufactured in a batch manner and a semiconductor element formed on at least one of the rest of the semiconductor substrates manufactured in a batch manner are different from each other, wherein all the heating steps are performed with the manufacture in a batch manner or all the heating steps except for only an arbitrary heating step with an arbitrary semiconductor substrate are performed with the manufacture in a batch manner in a manufacturing process of the semiconductor element.

3. A semiconductor element as claimed in claim 1, the semiconductor element being formed on a semiconductor substrate manufactured by the manufacture of at least two semiconductor substrates in a batch manner and being the semiconductor element in which a semiconductor element formed on an arbitrary semiconductor substrate manufactured in a batch manner and a semiconductor element formed on at least one of the rest of the semiconductor substrates manufactured in a batch manner are different from each other, wherein the semiconductor substrate on which the semiconductor element different from the arbitrary semiconductor element is formed comprises a photoengraving step of photoengraving a different original picture in an arbitrary photoengraving step.

4. A semiconductor element as claimed in claim 1, wherein the semiconductor element is photoengraved by a photoengraving device which comprises a container for containing at least two masks, a conveyance mechanism for conveying a desired mask from the container to an exposure portion for photoengraving and for conveying the mask having been subjected to an exposure step from the exposure portion to the container, a storage equipment for previously storing at least one of an arbitrary manufacturing lot, a wafer thereof, and a mask that an arbitrary wafer of the lot desires, and a control equipment for instructing on conveyance of a mask from the container corresponding to the arbitrary wafer of the arbitrary lot as stored, and on exposure.

5. A semiconductor element as claimed in claim 1, wherein the semiconductor element is photoengraved by the photoengraving device which comprises the container for containing at least two masks, the conveyance mechanism for conveying a desired mask from the container to an exposure portion for photoengraving and for conveying the mask having been subjected to an exposure step from the exposure portion to the container, the storage equipment for previously storing at least one of an arbitrary manufacturing lot, a wafer thereof, and a mask that an arbitrary wafer of the lot desires, and the control equipment for instructing on conveyance of a mask from the container corresponding to the arbitrary wafer of the arbitrary lot, which is stored, and on exposure, the photoengraving device comprising an inspection equipment for dust on a desired mask stored in advance, a mask cleaning equipment, and a remaining heat chamber for maintaining at least one mask at an arbitrary temperature.

6. A semiconductor element as claimed in claim 1, wherein:
the semiconductor element is manufactured by the photoengraving device which comprises the container for containing at least two masks, the conveyance mechanism for conveying a desired mask from the container to an exposure portion for photoengraving and for conveying the mask having been subjected to an exposure step from the exposure portion to the container, the storage equipment for previously storing at least one of an arbitrary manufacturing lot, a wafer thereof, and a mask that an arbitrary wafer of the lot desires, and the control equipment for instructing on conveyance of a mask from the container corresponding to the arbitrary wafer of the arbitrary lot as stored, and on exposure; and
a photoengraving step used by an arbitrary photoengraving device is determined in advance.

7. A photoengraving device in which an arbitrary original picture is transferred on a photosensitive film applied to a semiconductor substrate, wherein the original picture comprises an original picture displayed on an electronic display by inputting desired data.

8. A semiconductor element as claimed in claim 1, the semiconductor element being formed on a semiconductor substrate manufactured by the manufacture of at least two semiconductor substrates in a batch manner, and being characterized in that a semiconductor element formed on an arbitrary semiconductor substrate manufactured in a batch manner and a semiconductor element formed on at least one of the rest of the semiconductor substrates manufactured in a batch manner are different from each other, wherein the semiconductor element is manufactured by a photoengraving device for transferring an arbitrary original picture on a photosensitive film applied onto a semiconductor substrate, in which the original picture comprises an original picture displayed on an electronic display by inputting desired data.

9. A photoengraving device for transferring an arbitrary original picture, on a photosensitive film applied onto a semiconductor substrate, of a semiconductor element being formed on a semiconductor substrate manufactured by manufacture of at least two semiconductor substrates in a batch manner, and being characterized in that a semiconductor element formed on an arbitrary semiconductor substrate manufactured in a batch manner and a semiconductor element formed on at least one of the rest of the semiconductor substrates manufactured in a batch manner are different from each other, and of a method of manufacturing the semiconductor element, wherein:
the photoengraving device is constituted of a light source for exposing the photosensitive film, a lens for guiding light to the photosensitive film from the light source, a mirror array in which a plurality of minute mirrors are arranged in an array, a driving device for moving the minute mirrors of the mirror array with an arbitrary angle, and a control equipment thereof;
the light source, the lens, the mirror array are arranged such that the light from the light source is reflected at the mirror array to reach the photosensitive film;
the minute mirrors are driven by the driving device to be moved to two positions corresponding with an angle such that the reflected light reaches the photosensitive film and an angle such that the reflected light does not reach the photosensitive film; and the control equipment controls so that the entire mirror array reflects an arbitrary image onto the photosensitive film.

10. A semiconductor element photoengraved by a photoengraving device for transferring an arbitrary original picture on a photosensitive film applied onto a semiconductor substrate in a semiconductor element being formed on a semiconductor substrate manufactured by manufacture of at least two semiconductor substrates in a batch manner, and being characterized in that a semiconductor element formed on an arbitrary semiconductor substrate manufactured in a batch manner and a semiconductor element formed on at least one of the rest of the semiconductor substrates manufactured in a batch manner are different from each other, and a method of manufacturing the semiconductor element, the photoengraving device being characterized in that:
the device is constituted of a light source for exposing the photosensitive film, a lens for guiding light to the photosensitive film from the light source, a mirror array in which a plurality of minute mirrors are arranged in an array, a driving device for moving the minute mirrors of the mirror array with an arbitrary angle, and a control equipment thereof;
the light source, the lens, the mirror array are arranged such that the light from the light source is reflected at the mirror array to reach the photosensitive film;
the minute mirrors are driven by the driving device to be moved to two positions corresponding with an angle such that the reflected light reaches the photosensitive film and an angle such that the reflected light does not reach the photosensitive film; and
the control equipment controls so that the entire mirror array reflects an arbitrary image onto the photosensitive film.

11. A method of manufacturing a semiconductor element formed on a semiconductor substrate manufactured by manufacture of at least two semiconductor substrates in a batch manner, wherein a semiconductor element formed on an arbitrary semiconductor substrate manufactured in a batch manner and a semiconductor element formed on at least one of the rest of the semiconductor substrates manufactured in a batch manner are different from each other.

12. A method of manufacturing a semiconductor element, the semiconductor element being formed on a semiconductor substrate manufactured by manufacture of at least two semiconductor substrates in a batch manner, and being the semiconductor element in which a semiconductor element formed on an arbitrary semiconductor substrate manufactured in a batch manner and a semiconductor element formed on at least one of the rest of the substrates manufactured in a batch manner are different from each other, wherein all the heating steps are performed with the manufacture in a batch manner or all the heating steps except for only an arbitrary heating step with an arbitrary semiconductor substrate are performed with the manufacture in a batch manner in a manufacturing process of the semiconductor element.

13. A method of manufacturing a semiconductor element, the semiconductor element being formed on a semiconductor substrate manufactured by manufacture of at least two semiconductor substrates in a batch manner and being the semiconductor element in which a semiconductor element formed on an arbitrary semiconductor substrate manufactured in a batch manner and a semiconductor element formed on at least one of the rest of the semiconductor substrates manufactured in a batch manner are different from each other, wherein only the semiconductor substrate on which the semiconductor element different from the arbitrary semiconductor element is formed comprises a photoengraving step of photoengraving a different original picture in an arbitrary photoengraving step.

14. A method of manufacturing a semiconductor element photoengraved by a photoengraving device which comprises a container for containing at least two masks, a conveyance mechanism for conveying a desired mask from the container to an exposure portion for photoengraving and for conveying the mask having been subjected to an exposure step from the exposure portion to the container, a storage equipment for previously storing at least one of an arbitrary manufacturing lot, a wafer thereof, and a mask that an arbitrary wafer of the lot desires, and a control equipment for instructing on conveyance of a mask corresponding to the arbitrary wafer of the arbitrary lot as stored, and on exposure.

15. A method of manufacturing a semiconductor element photoengraved by a photoengraving device which comprises the container for containing at least two masks, the conveyance mechanism for conveying a desired mask from the container to an exposure portion for photoengraving and for conveying the mask having been subjected to an exposure step from the exposure portion to the container, the storage equipment for previously storing at least one of an arbitrary manufacturing lot, a wafer thereof, and a mask that an arbitrary wafer of the lot desires, and the control equipment for instructing on conveyance of a mask from the container corresponding to the arbitrary wafer of the arbitrary lot as stored, and on exposure, the photoengraving device comprising an inspection equipment for dust on a desired mask stored in advance, a mask cleaning equipment, and a remaining heat chamber for maintaining at least one mask at an arbitrary temperature.

16. A method of manufacturing a semiconductor element, the semiconductor element being manufactured by the photoengraving device which comprises the container for containing at least two masks, the conveyance mechanism for conveying a desired mask from the container to an exposure portion for photoengraving and for conveying the mask having been subjected to an exposure step from the exposure portion to the container, the storage equipment for previously storing at least one of an arbitrary manufacturing lot, a wafer thereof, and a mask that an arbitrary wafer of the lot desires, and the control equipment for instructing on conveyance of a mask from the container corresponding to the arbitrary wafer of the arbitrary lot as stored, and on exposure, wherein a photoengraving step used by an arbitrary photoengraving device is determined in advance.

17. A photoengraving device in which an arbitrary original picture is transferred on a photosensitive film applied to a semiconductor substrate, wherein the original picture comprises an original picture displayed on an electronic display by inputting desired data.

18. A method of manufacturing a semiconductor element, the semiconductor element being formed on a semiconductor substrate manufactured by manufacture of at least two semiconductor substrates in a batch manner, and being characterized in that a semiconductor element formed on an arbitrary semiconductor substrate manufactured in a batch manner and a semiconductor element formed on at least one of the rest of the semiconductor substrates manufactured in a batch manner are different from each other, wherein the semiconductor element is manufactured by an photoengraving device for transferring an arbitrary original picture on a photosensitive film applied onto a semiconductor substrate, the original picture comprising an original picture displayed on an electronic display by inputting desired data.

19. A method of manufacturing a semiconductor element photoengraved by a photoengraving device for transferring an arbitrary original picture, on a photosensitive film applied onto a semiconductor substrate, of a semiconductor element being formed on a semiconductor substrate manufactured by manufacture of at least two semiconductor substrates in a batch manner, and being characterized in that a semiconductor element formed on an arbitrary semiconductor substrate manufactured in a batch manner and a semiconductor element formed on at least one of the rest of the semiconductor substrates manufactured in a batch manner are different from each other, and of a method of manufacturing the semiconductor element, wherein:
the photoengraving device is constituted of a light source for exposing the photosensitive film, a lens for guiding light to the photosensitive film from the light source, a mirror array in which a plurality of minute mirrors are arranged in an array, a driving device for moving the minute mirrors of the mirror array with an arbitrary angle, and a control equipment thereof;
the light source, the lens, the mirror array are arranged such that the light from the light source is reflected at the mirror array to reach the photosensitive film;
the minute mirrors are driven by the driving device to be moved to two positions corresponding with an angle such that the reflected light of the minute mirror reaches the photosensitive film and an angle such that the reflected light does not reach the photosensitive film; and
the control equipment controls such that the entire mirror array reflects an arbitrary image onto the photosensitive film.
